(19) United States
(12) Patent Application Publication
(10) Pub. No.: US 2025/0098133 A1
(43) Pub. Date: Mar. 20, 2025

(54) REEL LOADING DEVICE

(71) Applicant: FUJI CORPORATION, Chiryu (JP)

(72) Inventors: Daiki SUZUKI, Toyokawa-shi (JP); Masataka IWASAKI, Anjo-shi (JP)

(73) Assignee: FUJI CORPORATION, Chiryu (JP)

(21) Appl. No.: 18/726,539

(22) PCT Filed: Feb. 7, 2022
(86) PCT No.: PCT/JP2022/004748

§ 371 Date: Jul. 3, 2024

(51) Int. Cl. H05K 13/02; H05K 13/04

(52) U.S. Cl. CPC H05K 13/021; H05K 13/0419

(57) ABSTRACT

A reel loading device includes: a feeder holding section capable of holding multiple types of tape feeders having different mechanisms configured to feed and move a carrier tape fed out from a detachable and rotatable reel; a dedicated loading unit provided in multiple types corresponding to types of the tape feeders, each capable of executing a loading process of loading the reel to the tape feeder such that the tape feeder is capable of feeding and moving the carrier tape in a state where the tape feeder of a corresponding type is held by the feeder holding section; and a moving mechanism configured to selectively move each of the multiple types of dedicated loading units between a retraction position and a loading position relative to the tape feeder held by the feeder holding section, in accordance with the execution of the loading process.

### TECHNICAL FIELD

The present description relates to a reel loading device.

### BACKGROUND ART

As a representative example of a board work machine that performs board work including component mounting on a board, there is a component mounter that performs component mounting work. Many component mounters use a tape feeder that performs component feeding by conveying a carrier tape in which components are accommodated in a state of performing component mounting. Conventionally, reel loading work of setting a carrier tape wound around a reel on a tape feeder has been performed by an operator. In recent years, a technique for automating the reel loading work on a tape feeder has been developed (for example, see Patent Literature 1).

The reel loading device disclosed in Patent Literature 1 guides a carrier tape pulled out from a tape reel attached to the tape feeder, from a tape inlet on a rear end side of the tape feeder to a tape feeding guide on a front end side, and processes the tip end portion of the carrier tape to head out a component. With this configuration, it is possible to automatically set the carrier tape pulled out from the tape reel in the tape feeder.

### PATENT LITERATURE

Patent Literature 1: WO 2013/132599

### BRIEF SUMMARY

### Technical Problem

Here, multiple types of tape feeders are provided in accordance with a mechanism that routes a carrier tape in the tape feeder, a processing mechanism of a cover tape after a component is taken out by the carrier tape, and the like. However, in the technique of Patent Literature 1, the reel loading device does not support multiple types of tape feeders. Therefore, in order to support multiple types of tape feeders, it is necessary to prepare a dedicated reel loading device for each of various types of tape feeders. Thus, a space for installing the reel loading device becomes excessive in order to perform a reel loading process on multiple types of tape feeders.

An object of the present description is to provide a reel loading device capable of executing a reel loading process on multiple types of tape feeders in a space-saving manner.

### Solution to Problem

The present description discloses a reel loading device including: a feeder holding section capable of holding multiple types of tape feeders having different mechanisms configured to feed and move a carrier tape fed out from a detachable and rotatable reel; a dedicated loading unit provided in multiple types corresponding to types of the tape feeders, each capable of executing a loading process of loading the reel to the tape feeder such that the tape feeder is capable of feeding and moving the carrier tape in a state where the tape feeder of a corresponding type is held by the feeder holding section; and a moving mechanism configured to selectively move each of the multiple types of dedicated loading units between a retraction position and a loading position relative to the tape feeder held by the feeder holding section, in accordance with the execution of the loading process.

With the disclosed configuration, it is possible to selectively move multiple dedicated loading units with respect to one feeder holding section and perform a reel loading process on the tape feeder of a corresponding type. Therefore, it is possible to execute the reel loading process on the multiple types of tape feeders in a space-saving manner.

### BRIEF DESCRIPTION OF DRAWINGS

FIG. 1 is a perspective view of a reel loading device according to an embodiment.

FIG. 2 is a plan view of the reel loading device.

FIG. 3 is a perspective view of a feeder holding section and a tape feeder.

FIG. 4 is a perspective view of a dedicated loading unit and a moving mechanism.

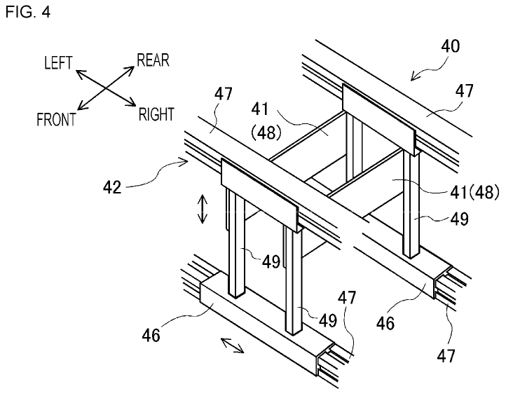

FIG. 5 is a plan view of the dedicated loading unit and the moving mechanism.

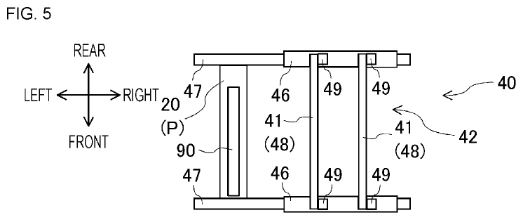

FIG. 6 is a plan view showing an operation of removing a reel from the tape feeder and a preparation operation of preparing the reel to be attached to the tape feeder.

FIG. 7 is a plan view showing a collection operation of collecting the removed reel and an attachment operation of attaching the reel to the tape feeder.

FIG. 8 is a flowchart of an example of a control routine executed in the reel loading device.

### DESCRIPTION OF EMBODIMENTS

### 1. Configuration of Reel Loading Device

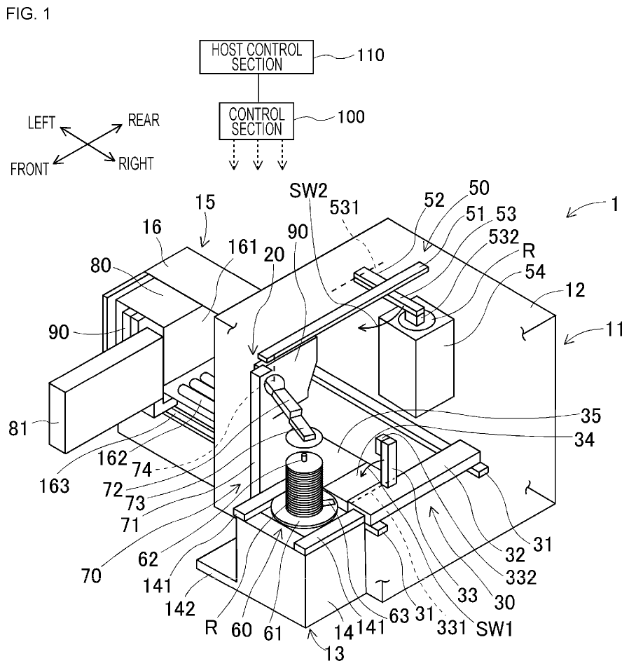

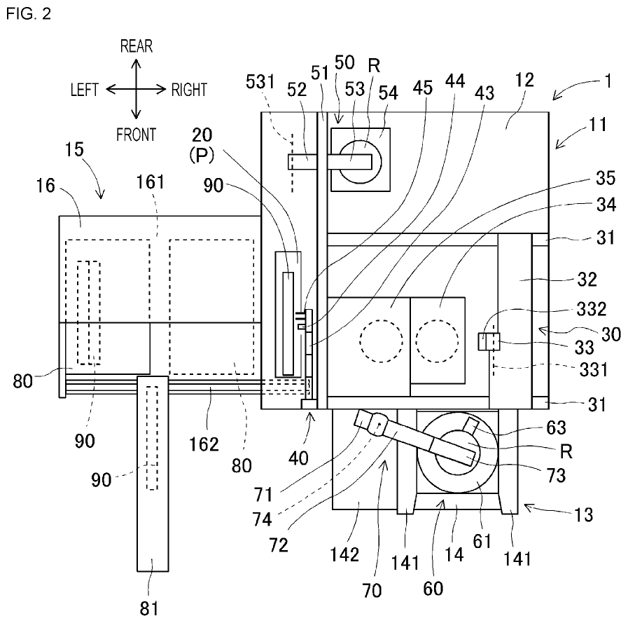

A configuration of reel loading device 1 in an embodiment will be described. In the embodiment, front, rear, left, and right directions are defined as shown in FIGS. 1 and 2 for convenience.

Reel loading device 1 is a device that automatically executes a loading process of loading reel R to tape feeder (simply referred to as a feeder below) 90. The loading process of reel R includes a process of enabling carrier tape T fed out from reel R to be fed and moved to feeder 90. The loading process of reel R may include a process of automatically attaching and detaching reel R itself to and from a reel attachment portion of feeder 90. In the following description, it is assumed that reel loading device 1 automatically attaches and detaches reel R to and from the reel attachment portion of feeder 90, and feeds out and sets the carrier tape from reel R to feeder 90 to be feedable and movable.

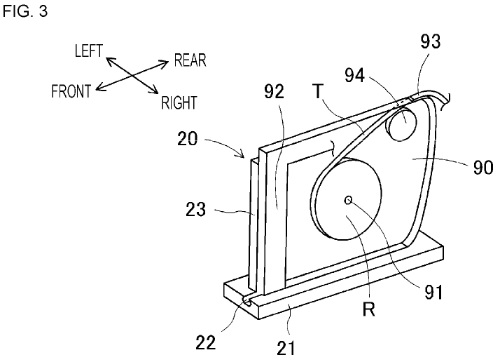

First, a configuration of feeder 90 will be described with reference to FIG. 3. Feeder 90 is a device that is detachably equipped at a component mounter and feeds and moves carrier tape T in which components are accommodated. Reel R around which carrier tape T is wound is detachably and rotatably supported by feeder 90. Feeder 90 supplies components by feeding and moving carrier tape T in a state of supporting reel R. Reel R is formed in a disc shape. An identification code for identifying individual reel R is attached to reel R.

Carrier tape T is a tape that accommodates component. Carrier tape T includes a base tape provided with a cavity portion that accommodates components, and a cover tape that covers the cavity portion of the base tape. The cavity portions are provided at a constant pitch in a tape longitudinal direction. The base tape is further provided with sprocket holes. The sprocket holes are provided at a constant pitch in the tape longitudinal direction along one side edge of the base tape.

The cover tape is adhered to the upper surface of the base tape in a normal state, and is peeled off from the base tape immediately before the component is taken out from the cavity portion. The cover tape may be brought back to come into contact with the base tape after the component is taken out from the cavity portion, and may be wound integrally with the base tape, or may be independently wound in a path different from the base tape after the component is taken out from the cavity portion.

Feeder 90 is formed into a thin type having a small width dimension in a right-left direction. The right side of feeder 90 is widely open at the central portion in order to facilitate attachment and detachment of reel R. Multiple types of reels R are provided corresponding to the material of carrier tape T and further corresponding to the tape width dimension of carrier tape T and the width dimension of reels R. Multiple types of feeders 90 are provided corresponding to the types of reels R or the types of carrier tapes T. The multiple types of feeders 90 have different mechanisms that feed and move carrier tape T.

Examples of the type of feeder 90 include a type in which the half of the cover tape is peeled off from the base tape, the cover tape is brought back to come into contact with the base tape after the component is taken out from the cavity portion, and the cover tape is wound integrally with the base tape, and a type in which the cover tape is completely peeled off from the base tape, and the cover tape is independently wound in a path different from the base tape after the component is taken out from the cavity portion.

Feeder 90 has reel holding shaft 91. Reel holding shaft 91 is provided at a substantially central position when feeder 90 is viewed from the side. Reel holding shaft 91 protrudes rightward from left side plate 92. Reel holding shaft 91 is fitted into a center hole formed at a center of reel R to detachably and rotatably hold reel R.

Feeder 90 includes component supply section 93, sprocket 94, and a tape peeling section (not shown). Component supply section 93 is provided near the rear end of the upper surface of feeder 90. Sprocket 94 is disposed on the front side of component supply section 93 and is rotatably supported by side plate 92. The teeth of sprocket 94 are fitted into sprocket holes of carrier tape T. Sprocket 94 is intermittently driven by a drive motor (not shown), and feeds and moves carrier tape T at constant pitches. The tape peeling section peels off the cover tape constituting carrier tape T from the base tape so that the component in the cavity portion can be taken out by component supply section 93.

An identification code for identifying individual feeder 90 is attached to feeder 90. Feeder 90 includes a feeder control section (not shown). The feeder control section stores an identification code of feeder 90 and an identification code of reel R and controls a component supply operation of feeder 90. Feeder 90 is held by feeder holding section 20 which will be described later in reel loading device 1. When feeder 90 is held by feeder holding section 20, the feeder control section is communicably connected to the main control section of reel loading device 1 by automatic fitting via a connector (not shown).

As shown in FIGS. 1 and 2, reel loading device 1 includes reel attachment and detachment section 11, reel supply section 13, and feeder supply section 15.

Reel attachment and detachment section 11 is a section that attaches and detaches reel R to and from feeder 90. Reel attachment and detachment section 11 is provided in device housing 12. Device housing 12 is a case having a rectangular parallelepiped shape, and is formed such that a front side and a left side thereof are partially opened. Reel attachment and detachment section 11 includes feeder holding section 20, reel attachment mechanism 30, tape loading mechanism 40, and reel removal mechanism 50.

Feeder holding section 20 holds feeder 90. As shown in FIG. 2, feeder holding section 20 is disposed at a position close to the left front in device housing 12. Feeder holding section 20 holds one feeder 90 at work execution position P with a vertical posture. As shown in FIG. 3, feeder holding section 20 includes bottom plate 21 and support plate 23.

Bottom plate 21 is a plate member extending in a front-rear direction. Bottom plate 21 has slit 22 formed in a groove shape extending in the front-rear direction. Feeder 90 is inserted from the front side to the rear side of slit 22 and held at work execution position P on bottom plate 21. Support plate 23 is a plate member that supports a lateral pressing load generated in feeder 90 when reel R is attached to feeder 90. Support plate 23 is provided to stand from bottom plate 21. Support plate 23 comes into contact with the left side surface of feeder 90 held at work execution position P.

Reel attachment mechanism 30 is a mechanism that changes reel R from a lying down posture to a vertical posture and attaches reel R to feeder 90 held at work execution position P. Reel attachment mechanism 30 is disposed on the right side of feeder holding section 20 in device housing 12. Reel attachment mechanism 30 includes pair of guide rails 31, moving table 32, attachment material 33, placement area 34, and temporary placement area 35. Reel attachment mechanism 30 may have a configuration in which a mechanism section that changes reel R from the lying down posture to the vertical posture is separated from a mechanism section that grips and attaches reel R in the vertical posture to feeder 90.

Pair of guide rails 31 extend in the right-left direction at a front edge position of device housing 12 and at a substantially central position in the front-rear direction, and are disposed in parallel to be spaced apart from each other. Moving table 32 is formed to extend in the front-rear direction, and is mounted across the upper sides of pair of guide rails 31. Moving table 32 can reciprocate along guide rails 31 between feeder holding section 20 and a standby position on the right side of feeder holding section 20.

Attachment material 33 is a member that detachably collects and moves reel R. Attachment material 33 is formed in a substantially square bar shape, and is provided to extend upward from the right side surface of moving table 32. Attachment material 33 faces reel holding shaft 91 of feeder 90 held at work execution position P. That is, attachment material 33 is located in a right direction from reel holding shaft 91.

Attachment material 33 swings around swing shaft 331 provided at a position close to moving table 32, between an upright posture and a horizontal posture falling down to the left side (see arrow SW1 shown in FIG. 1). Collection section 332 is provided at an end portion on a side of attachment material 33 away from swing shaft 331. Collection section 332 detachably collects reel R. Collection section 332 is configured with, for example, a gripping mechanism that grips a claw portion formed on reel R or the peripheral edge of reel R, a pickup mechanism that picks up reel R using negative pressure, or the like.

Placement area 34 is an area in which reel R to be attached next to feeder 90 is placed in the lying down posture. Placement area 34 is provided at a position on the right side between pair of guide rails 31. Temporary placement area 35 is an area in which, when reel attachment mechanism 30 changes the use order of reels R, reels R are temporarily placed in the lying down posture and the use order is changed later. Temporary placement area 35 is provided on the left side of placement area 34 between pair of guide rails 31. There is a case where reel R placed in temporary placement area 35 is not used as a result. Temporary placement area 35 may be formed widely so that multiple reels R can be temporarily placed. Moving table 32 and attachment material 33 move above placement area 34 and temporary placement area 35, respectively.

Tape loading mechanism 40 is a mechanism that performs a loading process in a state in which carrier tape T can be fed and moved in feeder 90. Tape loading mechanism 40 is disposed close to feeder holding section 20 (not shown in FIG. 1). Tape loading mechanism 40 includes dedicated loading unit 41 and moving mechanism 42.

Dedicated loading unit 41 is a unit that executes the loading process of loading reel R to feeder 90. Multiple types of dedicated loading units 41 are provided corresponding to the types of feeders 90, and multiple units are provided. Each of dedicated loading units 41 executes the loading process in a state where feeder 90 of the corresponding type is held by feeder holding section 20, so that feeder 90 can feed and move carrier tape T. Dedicated loading unit 41 may have a function of cutting a guide tape added to the tip of carrier tape T and loading the cut end thereof until the cut end thereof engages with sprocket 94, with respect to feeder 90 to which new reel R is attached.

The multiple types of dedicated loading units 41 have different structures or shapes in accordance with the types of corresponding feeders 90. In the present example, it is assumed that tape loading mechanism 40 includes two types of dedicated loading units 41. Dedicated loading unit 41 is configured with, for example, an articulated robot, and as a specific example, includes articulated arm 43, camera 44, and multiple fingers 45.

Articulated arm 43 is configured to freely rotate or bend an arm, and can freely adjust the positions and orientations of camera 44 and finger 45. Camera 44 images feeder 90 at work execution position P to detect the positions and the states of reel R and carrier tape T. Camera 44 is attached to the tip end portion of articulated arm 43. Each finger 45 can perform a moving operation, a twisting operation, and the like in addition to the operation of gripping and releasing a work target. Multiple fingers 45 are provided to be arranged with camera 44 at the tip end portion of articulated arm 43.

Prior to the loading operation, multiple fingers 45 peel off a fastening seal fastening the tip of carrier tape T. Then, multiple fingers 45 are loaded until the tip of carrier tape T is engaged with sprocket 94, so that carrier tape T can be fed and moved. Multiple fingers 45 can facilitate the peeling operation and the loading operation by rotating reel R around reel holding shaft 91 as necessary. Tape loading mechanism 40 maintains a retracted posture in which articulated arm 43 is bent so as not to hinder the attaching and detaching operation of reel R in a time period other than the operation time.

Moving mechanism 42 is a mechanism that moves each dedicated loading unit 41 between a retraction position and a loading position relative to feeder 90 held by feeder holding section 20. Specifically, moving mechanism 42 can independently lift and lower the multiple types of dedicated loading units 41 in an up-down direction, and can integrally move the multiple types of dedicated loading units 41 in the right-left direction. Moving mechanism 42 may independently move the multiple types of dedicated loading units 41 in the right-left direction.

Moving mechanism 42 selectively moves each of the multiple types of dedicated loading units 41 between the retraction position and the loading position in accordance with execution of the loading process on feeder 90. The loading position is a position of dedicated loading unit 41 at which reel R or carrier tape T can be loaded to feeder 90 held by feeder holding section 20 at work execution position P. The loading position is located on the lower stage side in the up-down direction.

The retraction position is a position of dedicated loading unit 41 where reel R or carrier tape T cannot be loaded to feeder 90 held by feeder holding section 20 at work execution position P, and even though horizontal holding table 46 which will be described later moves in the right-left direction along right and left guide rails 47, interference with feeder 90, other dedicated loading unit 41, and the like does not occur. The retraction position is located at the upper stage side of the loading position.

Moving mechanism 42 includes horizontal holding table 46, right and left guide rails 47, up-down moving table 48, and up-down guide rail 49.

Horizontal holding table 46 is a base that holds dedicated loading unit 41 to be movable in the right-left direction. Horizontal holding table 46 is configured to be able to collectively hold multiple dedicated loading units 41. Horizontal holding table 46 is held to be slidable in the right-left direction along right and left guide rails 47.

Right and left guide rails 47 are guide rails that move horizontal holding table 46 in the right-left direction. Right and left guide rails 47 extend in the right-left direction, and four right and left guide rails 47 are provided on the upper, lower, front, and rear sides. Horizontal holding table 46 is movable in the right-left direction along right and left guide rails 47. Horizontal holding table 46 moves by driving of a motor. Horizontal holding table 46 can move each dedicated loading unit 41 leftward from the right side of feeder holding section 20 to the loading position.

Up-down moving table 48 is a base that holds dedicated loading unit 41 such that dedicated loading unit 41 is able to be lifted and lowered in the up-down direction. Up-down moving table 48 is provided for each dedicated loading unit 41, and is configured to be able to hold corresponding dedicated loading unit 41 one by one. Each up-down moving table 48 is held to be slidable in the up-down direction along up-down guide rail 49. Each up-down moving table 48 may be separate from the main body base portion of dedicated loading unit 41, or may be integrated with the main body base portion.

Up-down guide rail 49 is a guide rail that moves up-down moving table 48 in the up-down direction. Up-down guide rail 49 is attached and fixed to horizontal holding table 46. Up-down guide rail 49 extends in the up-down direction, and four up-down guide rails 49 are provided on the left, right, front, and rear sides. Each up-down moving table 48 is movable in the up-down direction along pair of front and rear up-down guide rails 49. Each up-down moving table 48 moves by driving of a motor. Each up-down moving table 48 can lift and lower corresponding dedicated loading unit 41 on the right of work execution position P.

Reel removal mechanism 50 is a mechanism that removes reel R from feeder 90 held at work execution position P. Reel removal mechanism 50 is disposed on the right side of feeder holding section 20, and is located above reel attachment mechanism 30. Reel removal mechanism 50 includes guide rail 51, moving table 52, removal material 53, and collection box 54.

Guide rail 51 is provided near the ceiling of device housing 12 and extends in the front-rear direction. Moving table 52 is formed to extend in the right-left direction, and is mounted on the lower side of guide rail 51. Moving table 52 can reciprocate along guide rails 51 between feeder holding section 20 and a standby position on the rear side of feeder holding section 20.

Removal material 53 is a member that detachably collects and moves reel R. Removal material 53 is formed in a thick plate shape that is longer than moving table 52, and is provided to extend in the right-left direction on the lower side of moving table 52. Removal material 53 swings around swing shaft 531 provided near the left end of moving table 52 between a horizontal posture and a vertical posture falling downward (see arrow SW2 shown in FIG. 1). Collection section 532 is provided at an end portion on the side of removal material 53 away from swing shaft 531. Collection section 532 detachably collects reel R. Collection section 532 may adopt the similar collection method to collection section 332 of reel attachment mechanism 30, or may be different.

Collection box 54 is a box body for collecting removed reel R. Collection box 54 is disposed below removal material 53 when moving table 52 moves to the standby position. Collection box 54 is formed in a box shape opening upward. Collection box 54 can automatically collect reel R that falls down due to release of collection section 532 of removal material 53.

Reel supply section 13 is a section that supplies reels R. Reel supply section 13 is disposed to be coupled to the front side of reel attachment and detachment section 11. Reel supply section 13 is provided on base 14 having a box shape. Base 14 corresponds to a device housing smaller than device housing 12. Reel supply section 13 includes reel holding body 60 and reel transfer mechanism 70.

Base 14 includes pair of guide plates 141. Pair of guide plates 141 extend in the front-rear direction on the left side and the right side of the upper surface of base 14. Reel holding body 60 is detachably placed between pair of guide plates 141 of base 14. Pair of guide plates 141 are formed such that the inner sides facing each other on the front side are tapered and a spacing distance on the front side is larger than a spacing distance on the rear side. With this structure, reel holding body 60 can easily enter to base 14 from the front of base 14.

Reel holding body 60 is a section that stacks and holds multiple reels R (for example, 20 reels) in the lying down posture. Reel R is not limited to a new reel, and may be a reel in which carrier tape T is used halfway. Reel holding body 60 includes circular plate-shaped holding plate 61 and round rod-shaped holding shaft 62. Holding plate 61 is horizontally disposed. Holding shaft 62 is provided upright upward from the center of holding plate 61. Holding shaft 62 is fitted into a center hole of reel R. Reel holding body 60 can hold reels R in a state where the center holes of reels R are aligned even though reels R having different diameters and width dimensions are mixed. Identification code 63 is added near the outer periphery of the upper surface of holding plate 61. Identification code 63 includes information for specifying an individual of reel holding body 60. Identification code 63 is provided by printing or attaching a seal.

The worker procures multiple reels R based on work instruction data and performs a stacking work of stacking reels R on reel holding body 60. The work instruction data is for an instruction of the work content of the loading process to be executed by reel loading device 1. The work instruction data is data in which the type information of multiple reels R sequentially required with the production progress of the component mounter is associated with the type information of multiple feeders 90 applicable to reels R.

Reel transfer mechanism 70 is a mechanism that transfers reels R between reel holding body 60, and placement area 34 or temporary placement area 35 of reel attachment mechanism 30. Reel transfer mechanism 70 is disposed on plate seat 142 extending leftward from a bottom portion of base 14. Reel transfer mechanism 70 includes support column 71, arm 72, and collection section 73. Support column 71 stands vertically upward from a position near the rear portion of plate seat 142. Arm 72 is provided to be able to lift and lower with respect to support column 71. Arm 72 is rotatable in a horizontal plane about rotation shaft 74 provided at a position close to support column 71.

Collection section 73 detachably collects reel R. Collection section 73 is provided to be extendable and contractible with respect to arm 72. Collection section 73 is attached and detached in a state where reel R is held horizontally. Collection section 73 may adopt the similar collection method to collection section 332 of reel attachment mechanism 30 and collection section 532 of reel removal mechanism 50, or may be different. A code reader (not shown) is provided to collection section 73. The code reader can read identification code 63 of reel holding body 60 and can read the identification code of the uppermost stacked reel R.

Reel transfer mechanism 70 takes out reel R from reel holding body 60 by the operation of arm 72 and collection section 73. In addition, reel transfer mechanism 70 places taken-out reel R in placement area 34 or temporary placement area 35 in the lying down posture by the operation of arm 72 and collection section 73. Reel transfer mechanism 70 sequentially picks up multiple reels R stacked on reel holding body 60 from the upper side.

Feeder supply section 15 is a section that supplies feeder 90. Feeder supply section 15 is disposed to be coupled to the left side of reel attachment and detachment section 11. Feeder supply section 15 is provided in device housing 16. Device housing 16 is smaller than device housing 12. Device housing 16 has storage space 161 opened forward.

Feeder supply section 15 includes feeder accommodation section 80 and feeder conveyance section 81. Feeder accommodation section 80 is a box-shaped section that accommodates feeder 90. Feeder accommodation section 80 is detachably accommodated in storage space 161. Storage space 161 can store two feeder accommodation sections 80 to be arranged in the right-left direction. Multiple roller conveyors 162 extending in the right-left direction are provided to be arranged in the front-rear direction on the bottom surface of storage space 161.

Feeder accommodation section 80 is formed in a box shape with an open front side. Multiple slits having the same shape as slits 22 of feeder holding section 20 are formed on the bottom surface of feeder accommodation section 80. Feeder accommodation section 80 can accommodate multiple (for example, 20) feeders 90 to be arranged in the right-left direction in the vertical posture.

When multiple feeders 90 are accommodated in feeder accommodation section 80 and feeder accommodation section 80 is stored in storage space 161, the feeder control section of each feeder 90 is communicably connected to the main control section by automatic fitting via a connector (not shown). An identification code for identifying individual feeder accommodation section 80 is added to each feeder accommodation section 80. The worker procures multiple feeders 90 to be used based on the above-described work instruction data, and performs accommodation work of accommodating feeders 90 in feeder accommodation section 80. The number of feeder accommodation sections 80 stored in storage space 161 may be one or three or more.

Guide rail 163 is provided in a front lower portion of storage space 161 of device housing 16. Guide rail 163 extends substantially entirely in the right-left direction of storage space 161, and further extends to the front side of feeder holding section 20. Feeder conveyance section 81 is mounted on guide rail 163. Feeder conveyance section 81 reciprocates along guide rail 163 between feeder accommodation section 80 and feeder holding section 20.

Feeder conveyance section 81 is formed in a box shape. Feeder conveyance section 81 has an opening portion that is open to the rear side. Feeder conveyance section 81 includes an incorporation space for temporarily incorporating feeder 90 and a feeder operation mechanism that takes feeder 90 into and out of the incorporation space via the opening portion. Feeder conveyance section 81 can pull out feeder 90 from feeder accommodation section 80 or feeder holding section 20, and conversely insert feeder 90 into feeder accommodation section 80 or feeder holding section 20. In order to prevent inadvertently approaching of a worker, it is preferable to provide an openable and closable safety fence (not shown) on the front side of reel supply section 13 and feeder supply section 15.

### 2. Configuration Related to Control and Drive of Reel Loading Device 1

Next, a configuration related to control and driving of reel loading device 1 will be described. As shown in FIG. 1, reel loading device 1 includes control section 100. Control section 100 is configured using a computer device having a communication function and a man-machine interface function.

Control section 100 is communicably connected to the feeder control section by using, as a target, feeder 90 held by feeder holding section 20 and feeder 90 accommodated in feeder accommodation section 80. Control section 100 is communicably connected to host control section 110. Host control section 110 stores feeder correspondence data in which the identification code of feeder accommodation section 80 is associated with the identification code of each accommodated feeder 90. The feeder correspondence data is created during the above-described accommodation work. In addition, host control section 110 stores reel correspondence data in which the identification code of reel holding body 60 is associated with the identification code of each held reel R. The reel correspondence data is created during the above-described stacking work. Host control section 110 stores feeder information in which the identification code of feeder 90 is associated with type information of feeder 90. Host control section 110 stores reel information in which the identification code of reel R is associated with the type information of reel R.

Control section 100 acquires the work instruction data from host control section 110 before starting the loading process. Control section 100 acquires the feeder correspondence data and the reel correspondence data from host control section 110 together with the work instruction data. Control section 100 may include a code reader (such as a two-dimensional code reader) that reads the identification code of feeder accommodation section 80, and may acquire the feeder correspondence data by referring to host control section 110 for the read identification code.

Reel attachment mechanism 30, tape loading mechanism 40, reel removal mechanism 50, and reel transfer mechanism 70 are provided separately and have different drive sources, and can operate independently of each other. Control section 100 controls reel attachment mechanism 30, tape loading mechanism 40, reel removal mechanism 50, and reel transfer mechanism 70 to avoid interference between the mechanisms while operating separately in parallel, so as to efficiently perform the loading process.

Control section 100 controls the start and stop of a first motor that drives the movement of moving table 32 of reel attachment mechanism 30, and the change of a movement direction by switching between the forward rotation and the reverse rotation of the first motor. In addition, control section 100 controls a swinging operation of attachment material 33 and a collection operation of collection section 332.

Control section 100 controls the operations of articulated arm 43 and fingers 45 based on the detection result of camera 44 of tape loading mechanism 40. Control section 100 controls the start and stop of a second motor that drives the movement of moving table 52 of reel removal mechanism 50, and the change of a movement direction by switching between the forward rotation and the reverse rotation of the second motor. Furthermore, control section 100 controls a swinging operation of removal material 53 and a collection operation of collection section 532. Control section 100 controls a lifting and lowering operation and a rotating operation of arm 72 of reel transfer mechanism 70, and controls an extending and contracting operation and a collection operation of collection section 73.

In addition, control section 100 refers to host control section 110 for identification code 63 of reel holding body 60 read by the code reader, acquires the reel correspondence data, and identifies the individual of all reels R of reel holding body 60. Alternatively, the code reader may sequentially acquire the identification code attached to each reel R. Control section 100 controls the start and stop of a third motor that drives the movement of feeder conveyance section 81 and the change of a movement direction by switching between the forward rotation and the reverse rotation of the third motor.

Control section 100 acquires the work instruction data, feeder information, and reel information from host control section 110, acquires the identification code of feeder 90 held by feeder holding section 20, and acquires the identification code of reel holding body 60 or the identification code of reel R. Further, control section 100 selects feeder 90 applicable to the uppermost reel R of reel holding body 60 based on the work instruction data, the feeder information, the reel information, and the identification code. That is, control section 100 selects feeder 90 of the type corresponding to the type of reel R based on the identification information of recognized reel R and the identification information of feeder 90.

### 3. Operation of Reel Loading Device 1

Next, the operation of reel loading device 1 will be described with reference to FIGS. 2, 6, and 7. In reel loading device 1, multiple mechanisms can operate in parallel.

In an initial state, all dedicated loading units 41 of tape loading mechanism 40 are located at the retraction position on the upper stage side. The worker stores first feeder accommodation section 80 that accommodates multiple feeders 90 as targets of the loading process, in storage space 161. Further, the worker stores empty second feeder accommodation section 80 in storage space 161. According to this, feeder 90 on which the reel has been loaded is collected in second feeder accommodation section 80, and finally first feeder accommodation section 80 is empty.

Instead of the above operation, only one feeder accommodation section 80 may be used, and feeder 90 for which the loading process has been completed may be brought back to the original accommodation position. In addition, feeders 90 may be accommodated in two feeder accommodation sections 80 without a gap, and the loading process of the maximum number may be executed. In this operation, when the loading process to first feeder accommodation section 80 is completed and the loading process to second feeder accommodation section 80 is executed, first feeder accommodation section 80 in which the work has been performed can be exchanged with third feeder accommodation section 80 before the work is performed. By repeating this exchange, the loading process can be performed without interruption.

The worker further places reel holding body 60 that holds multiple reels R used for the loading process on base 14 of reel supply section 13. At this time, it is preferable that multiple feeders 90 accommodated in feeder accommodation section 80 and multiple reels R held by reel holding body 60 correspond to each other in a one-to-one manner without excess or deficiency. When the worker performs the accommodation work and the stacking work described above based on the work instruction data, the one-to-one correspondence relationship is satisfied and there is no excess or deficiency. The one-to-one correspondence relationship is satisfied even in a case where multiple types of feeders 90 and multiple types of reels R are mixed.

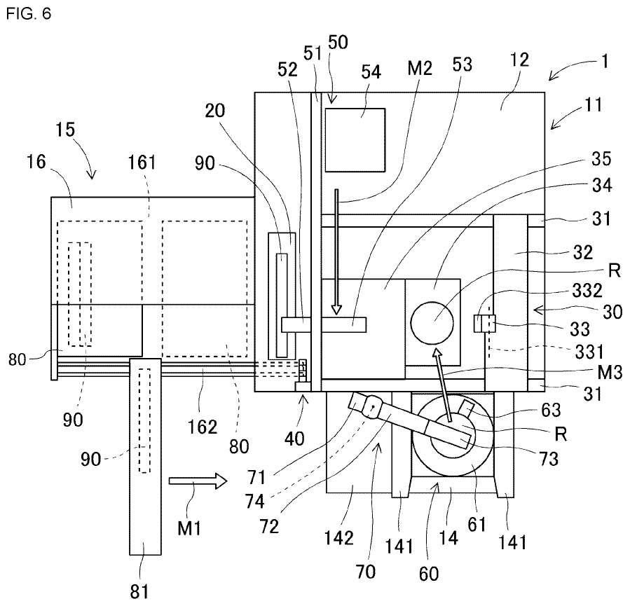

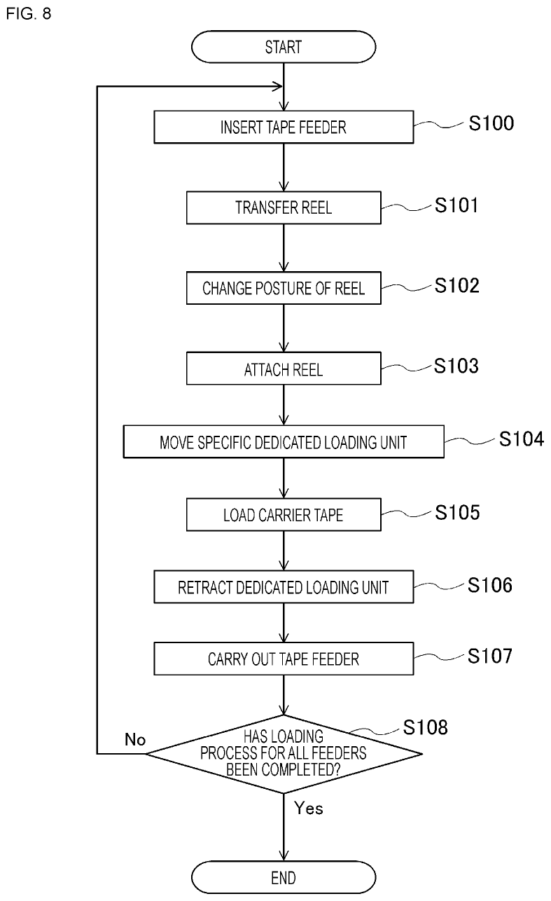

Control section 100 causes feeder conveyance section 81 to convey feeder 90 corresponding to the uppermost reel R of reel holding body 60. Feeder conveyance section 81 pulls out and incorporates feeder 90 from feeder accommodation section 80, moves to feeder holding section 20 (see arrow M1 shown in FIG. 6), and inserts incorporated feeder 90 into feeder holding section 20 (Step S100 shown in FIG. 8). As a result, feeder 90 is held at work execution position P. At this time, control section 100 reads the identification code of feeder 90.

When feeder 90 applicable to the uppermost reel R of reel holding body 60 is not accommodated in feeder accommodation section 80, the uppermost reel R is placed in temporary placement area 35 by reel transfer mechanism 70, and feeder 90 corresponding to second reel R is inserted into feeder holding section 20.

Control section 100 first checks the state of reel R of feeder 90 based on the read identification code of feeder 90 or the read identification code of reel R. When feeder 90 is used in the component mounter in advance, reel R may be in a used state in which a part of carrier tape T has been used, may be in a used state in which the entire carrier tape T has been used and is not available, or may not be attached to feeder 90 from the beginning. Control section 100 changes and executes the operation of each mechanism of reel loading device 1 in accordance with the reel state of feeder 90.

When reel R is attached to feeder 90, reel removal mechanism 50 removes reel R from feeder 90. Specifically, first, moving table 52 moves from the standby position to feeder holding section 20 (see arrow M2 shown in FIG. 6). Then, when removal material 53 swings from the horizontal posture to the vertical posture, collection section 532 abuts on reel R and collects reel R. Then, when removal material 53 returns from the vertical posture to the horizontal posture, collection section 532 pulls out reel R from reel holding shaft 91 and holds reel R in the horizontal posture.

At this time, control section 100 deletes the identification code of reel R from the storage section of the feeder control section of feeder 90. Further, control section 100 transmits the identification code of feeder 90 from which reel R is actually removed to host control section 110. At this time, control section 100 may transmit the identification code of the removed reel R together with the identification code of feeder 90 to host control section 110.

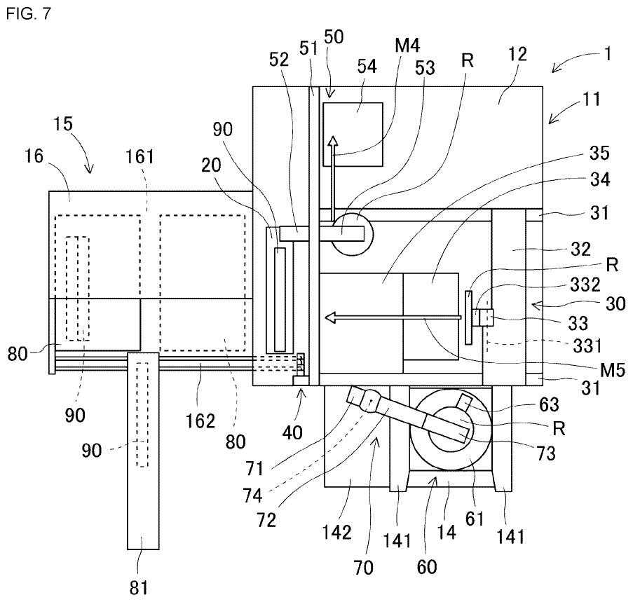

Next, reel removal mechanism 50 collects reel R. Specifically, first, moving table 52 moves from feeder holding section 20 to the standby position (see arrow M4 shown in FIG. 7). Then, collection section 532 releases reel R. As a result, released reel R automatically falls into collection box 54.

When reel R is removed from feeder 90 or when reel R is not originally attached to feeder 90, reel transfer mechanism 70 collects the uppermost reel R of reel holding body 60 by using collection section 73 and places reel R on placement area 34 (see arrow M3 shown in FIG. 6). In addition, when uppermost reel R is placed in temporary placement area 35, reel transfer mechanism 70 places second reel R in placement area 34. When placement in placement area 34 is performed (Step S101), reel transfer mechanism 70 brings collection section 73 back to above reel holding body 60.

Then, reel attachment mechanism 30 changes the posture of reel R in placement area 34 (Step S102). Specifically, first, when attachment material 33 falls down from the upright posture to the horizontal posture, collection section 332 abuts on reel R and collects reel R. At this time, since reel R is in the lying down posture, the placed position and posture of reel R are stabilized. As a result, collection section 332 can easily collect reel R.

Then, when attachment material 33 returns from the horizontal posture to the upright posture, collection section 332 changes reel R from the lying down posture to the vertical posture and holds reel R. When reels R in temporary placement area 35 are used, moving table 32 moves leftward by a predetermined distance before attachment material 33 falls down. After the above holding, the operation execution is postponed.

When a state in which interference between reel attachment mechanism 30 and reel removal mechanism 50 is avoided is achieved, reel attachment mechanism 30 attaches reel R to feeder 90 (Step S103). Specifically, moving table 32 moves to feeder 90 at work execution position P in a state in which collection section 332 holds reel R in the vertical posture. As a result, reel R moves forward straight toward reel holding shaft 91 (see arrow M5 shown in FIG. 7) and is automatically attached to reel holding shaft 91. The movement of moving table 32 can be performed simultaneously and parallel with the movement of moving table 52 to the standby position.

When the attachment of reel R is completed, control section 100 stores the identification code of reel R in the feeder control section of feeder 90. Further, control section 100 transmits the identification code of feeder 90 and the identification code of reel R that are actually combined to host control section 110 in association with each other. Thereafter, moving table 32 is retracted from feeder 90 and returns to the standby position.

When moving table 32 returns to the standby position, control section 100 performs control such that tape loading mechanism 40 is operated with respect to feeder 90 that has been inserted into feeder holding section 20 and held at work execution position P, before execution of the loading process of carrier tape T with respect to feeder 90. Specifically, control section 100 first specifies one dedicated loading unit 41 corresponding to feeder 90, and then controls moving mechanism 42 such that dedicated loading unit 41 is moved from the retraction position to be disposed at the loading position (Step S104).

Moving mechanism 42 is controlled as follows in a state where moving table 32 is retracted from feeder 90 at work execution position P. First, horizontal holding table 46 is moved leftward or rightward along right and left guide rails 47 from the retraction position of dedicated loading unit 41 so that one dedicated loading unit 41 corresponding to feeder 90 at work execution position P is located on the right side of feeder holding section 20. Thereafter, up-down moving table 48 is moved downward along up-down guide rails 49 so that dedicated loading unit 41 is lowered from the upper stage side and located at the lower stage side. Then, horizontal holding table 46 is moved leftward along right and left guide rails 47 so that dedicated loading unit 41 is located at the loading position. The movement in the right-left direction and the movement in the up-down direction may be performed simultaneously within a range in which interference between members does not occur.

Then, when dedicated loading unit 41 reaches the loading position, control section 100 controls dedicated loading unit 41 so that the loading process is executed on feeder 90 (Step S105). In this control, dedicated loading unit 41 at the loading position peels off the fastening tape at the tip of carrier tape T and loads carrier tape T until the tip of carrier tape T engages with sprocket 94. After the tip of carrier tape T is engaged with sprocket 94 as described above, feeder 90 may head out carrier tape T so that component supply section 93 can take out a component.

When the loading of carrier tape T to feeder 90 is completed as described above, dedicated loading unit 41 is brought back from the loading position to the retraction position (Step S106). Specifically, dedicated loading unit 41 first moves rightward from the loading position, and then rises and is brought back to the retraction position.

Control section 100 causes feeder conveyance section 81 to carry out feeder 90 on which carrier tape T has been loaded, from feeder holding section 20 (Step S107). Feeder conveyance section 81 pulls out and incorporates feeder 90 from feeder holding section 20, moves to feeder accommodation section 80, and inserts incorporated feeder 90 into feeder accommodation section 80. As a result, the loading process of reel R for one feeder 90 is completed.

Control section 100 repeatedly executes the loading process of reel R to each feeder 90 (Step S108). When the loading process of reels R into all feeders 90 is completed, the operation flow ends.

Thereafter, the worker conveys feeder accommodation section 80 that accommodates feeder 90 subjected to the loading process to the component mounter, and performs the setup change of feeder 90.

When reel R is temporarily placed in temporary placement area 35, the worker accommodates feeder 90 applicable to reel R in feeder accommodation section 80 and thus feeder 90 is held by feeder holding section 20, so that reel R can be loaded into feeder 90. Further, reel R left in temporary placement area 35 may be brought back to reel holding body 60 by reel transfer mechanism 70 and collected by the worker instead of being loaded to feeder 90.

As described above, in reel loading device 1 in the present embodiment, the loading process of reels R to multiple feeders 90 is automatically performed when the worker prepares multiple feeders 90 in feeder accommodation section 80 and prepares multiple reels R in reel holding body 60. Therefore, according to reel loading device 1, it is possible to achieve labor saving.

In addition, in reel loading device 1, tape loading mechanism 40 includes multiple types of dedicated loading units 41 corresponding to multiple types of feeders 90, and dedicated loading unit 41 used for the loading process can be selected corresponding to the type of feeder 90 held by feeder holding section 20. Specifically, tape loading mechanism 40 can selectively move each of multiple types of dedicated loading units 41 between the retraction position and the loading position relative to feeder 90, in accordance with execution of the loading process. Meanwhile, reel loading device 1 includes one feeder holding section 20 capable of holding one feeder 90, and can operate each of feeder conveyance section 81, reel attachment mechanism 30, and reel removal mechanism 50 with respect to one feeder holding section 20.

With this configuration, it is possible to perform the reel loading process on feeder 90 of the corresponding type by selectively moving multiple dedicated loading units 41 with respect to one feeder holding section 20 while performing the common work performed on feeder 90 using a common unit. The common work described above includes supply and holding of feeder 90, attachment and detachment of reel R, and the like. In addition, the common unit includes feeder holding section 20, reel attachment mechanism 30, reel removal mechanism 50, and feeder conveyance section 81.

Thus, it is not necessary to prepare the same number of feeder holding sections 20, reel attachment mechanisms 30, and the like as the number of types of feeders 90, and it is not necessary to prepare one reel loading device for each type of feeder 90. Therefore, the reel loading process on multiple types of feeders 90 can be executed in a space-saving manner by using one reel loading device 1.

Further, in reel loading device 1, each dedicated loading unit 41 of tape loading mechanism 40 lifts and lowers between the retraction position and the loading position in the up-down direction. In this configuration, the space for retracting multiple types of dedicated loading units 41 selectively moved to feeder holding section 20 needs only to be provided above feeder holding section 20, and it is not necessary to provide such a space in the horizontal direction, for example, on the front side, the rear side, or the like with respect to feeder holding section 20. Therefore, it is possible to reduce the installation space of one reel loading device 1 for executing the reel loading process on multiple types of feeders 90.

In the above embodiment, feeder holding section 20 is a non-binding example of a “feeder holding section”, dedicated loading unit 41 is a non-binding example of a “dedicated loading unit”, moving mechanism 42 is a non-binding example of a “moving mechanism”, control section 100 is a non-binding example of a “control section”, reel holding body 60, placement area 34 or temporary placement area 35, and collection box 54 are non-binding examples of a “reel placement section”, reel holding shaft 91 is a non-binding example of a “reel holding section”, and reel attachment mechanism 30, reel removal mechanism 50, and reel transfer mechanism 70 are non-binding examples of “reel transfer unit”.

### 4. Modified Embodiment

In the above embodiment, each dedicated loading units 41 of tape loading mechanism 40 is lifted and lowered between the retraction position and the loading position in the up-down direction. However, the present disclosure is not limited to this, and each dedicated loading unit 41 may move in the front-rear direction or the right-left direction without lifting and lowering in the up-down direction between the retraction position and the loading position, within a range in which interference with other mechanisms or members does not occur.

In the embodiment described above, moving mechanism 42 moves dedicated loading unit 41 with respect to fixed feeder holding section 20 (work execution position P). However, the present disclosure is not limited to this, and moving mechanism 42 may move feeder holding section 20 with respect to fixed dedicated loading unit 41 as long as feeder holding section 20 and dedicated loading unit 41 move relative to each other. At this time, the movement of feeder holding section 20 is performed on dedicated loading unit 41 corresponding to feeder 90 held by feeder holding section 20.

In the embodiment described above, the worker performs accommodation work of feeder 90 in feeder accommodation section 80, the stacking work of reels R on reel holding body 60, and the like. However, the present disclosure is not limited to this, and an automated guided vehicle or a robot may perform the above-described accommodation work, stacking work, or the like without depending on a worker. With the configuration of this modified embodiment, it is possible to further enhance the effect of labor saving.

Reel loading device 1 may have a configuration in which reel supply section 13 and feeder supply section 15 are omitted from the configuration of the embodiment. In this configuration, the worker inserts feeder 90 into feeder holding section 20, and places reel R in placement area 34 in the lying down posture. As a result, reel R is automatically attached to feeder 90, carrier tape T is automatically fed out from reel R, and carrier tape T is automatically loaded to feeder 90.

Reel loading device 1 may further have a configuration in which reel attachment mechanism 30 and reel removal mechanism 50 of reel attachment and detachment section 11 are omitted. In this configuration, the worker further attaches reel R to feeder 90 and then removes reel R. As a result, carrier tape T is automatically fed out from reel R attached to feeder 90, and carrier tape T is automatically loaded to feeder 90.

The present disclosure is not limited to the above-described embodiment and modification examples, and various changes can be made without departing from the spirit of the present disclosure.

### REFERENCE SIGNS LIST

1: reel loading device, 11: reel attachment and detachment section, 13: reel supply section, 15: feeder supply section, 20: feeder holding section, 30: reel attachment mechanism, 40: tape loading mechanism, 41: dedicated loading unit, 42: moving mechanism, 46: horizontal holding table, 47: right and left guide rails, 48: up-down moving table, 49: up-down guide rail, 50: reel removal mechanism, 60: reel holding body, 70: reel transfer mechanism, 80: feeder accommodation section, 81: feeder conveyance section, 90: tape feeder (feeder), 91: reel holding shaft, 94: sprocket, 100: control section, 110: host control section, R: reel, T: carrier tape

1. A reel loading device comprising:
a feeder holding section capable of holding multiple types of tape feeders having different mechanisms configured to feed out and move a carrier tape fed out from a detachable and rotatable reel;
a dedicated loading unit provided in multiple types corresponding to types of the tape feeders, each capable of executing a loading process of loading the reel to the tape feeder such that the tape feeder is capable of feeding and moving the carrier tape in a state where the tape feeder of a corresponding type is held by the feeder holding section; and
a moving mechanism configured to selectively move each of the multiple types of dedicated loading units between a retraction position and a loading position relative to the tape feeder held by the feeder holding section, in accordance with execution of the loading process.

2. The reel loading device according to claim 1, further comprising:
a control section configured to control the moving mechanism such that one dedicated loading unit corresponding to the tape feeder is disposed at the loading position before the execution of the loading process on the tape feeder held by the feeder holding section.

3. The reel loading device according to claim 1, further comprising:
a reel transfer unit configured to transfer the reels between a reel placement section on which the reel is placed and a reel holding section of the tape feeder held by the feeder holding section,
wherein the moving mechanism moves the dedicated loading unit of a corresponding type with respect to the feeder holding section in a state where the reel transfer unit is retracted from the tape feeder held by the feeder holding section.
